(19) United States
(12) Patent Application Publication
(10) Pub. No.: US 2015/0094403 A1
(43) Pub. Date: Apr. 2, 2015

(54) SURFACE-MODIFIED INORGANIC FILLER, METHOD FOR PREPARING THE SAME, EPOXY RESIN COMPOSITION AND INSULATING FILM INCLUDING THE SAME

(71) Applicant: SAMSUNG ELECTRO-MECHANICS CO., LTD., Suwon-Si (KR)

(72) Inventors: Ki Seok KIM, Suwon-Si (KR); Hwa Young LEE, Suwon-Si (KR); Ji Hye SHIM, Suwon-Si (KR)

(73) Assignee: SAMSUNG ELECTRO-MECHANICS CO., LTD., Suwon-Si (KR)

(21) Appl. No.: 14/250,130

(22) Filed: Apr. 10, 2014

(30) Foreign Application Priority Data
Sep. 30, 2013 (KR) 10-2013-0116384

(51) Int. Cl. C08K 9/06; H05K 1/03

(52) U.S. Cl. CPC C08K 9/06; H05K 1/0373
USPC 523/466; 556/413

(57) ABSTRACT

Disclosed herein is a surface-modified inorganic filler including an alkyl group and an amine group sequentially introduced on a surface thereof, wherein the alkyl group and the amine group are introduced on the surface of the inorganic filler in a weight ratio between the alkyl group and the amine group of 0.5:9.5 to 4:6. An epoxy resin composition including the surface-treated inorganic filler according to the present invention may have low dielectric loss rate and low coefficient of thermal expansion properties.

### CROSS REFERENCE TO RELATED ED APPLICATION

This application claims the benefit of Korean Patent Application No. 10-2013-0116384, filed on Sep. 30, 2013, entitled “Surface-modified Inorganic Filler, Method for Preparing the Same, Epoxy Resin Composition and Insulating Film Including the Same”, which is hereby incorporated by reference in its entirety into this application.

### BACKGROUND OF THE INVENTION

1. Technical Field

The present invention relates to a surface-modified inorganic filler, a method for preparing the same, an epoxy resin composition and an insulating film including the same.

2. Description of the Related Art

Recently, in accordance with miniaturization and high performance of electronic devices with a rapid development of electronics industry, high performance in a multilayer print wiring board is considered as an essential factor. In order to satisfy the high performance, high performance in an inter-layer insulating film which is a build-up film used for manufacturing a printed circuit board (PCB) is also considered as an essential factor. As a board gradually becomes thinned, a low coefficient of thermal expansion (CTE) and high modulus have been demanded for suppressing and controlling warpage of the thin layer board, and board materials having a low dielectric constant and a low dielectric loss rate for being applied to high speed input and output (HSIO) through ‘low roughness’ for forming a fine wiring and decrease in a signal loss rate in a high frequency signal have been demanded.

Various researches for developing the board materials having the low dielectric loss rate have been recently conducted. For example, the researches on an organic/inorganic hybrid complex manufactured by synthesizing an epoxy resin having a low dielectric constant property and a curing agent, using an epoxy resin having a low dielectric property and a curing agent, and including an inorganic filler having a low dielectric loss rate have been the most commonly conducted.

Various inorganic fillers such as alumina, silica, and the like, may be used as a filler of the board material, and a silica has been mainly used as the inorganic filler of the build-up film. The dielectric constant and the dielectric loss rate of the build-up insulating film have a large influence on a content of the silica having excellent dielectric properties, and in order to obtain a coefficient of thermal expansion of about 30 ppm or less and a low dielectric loss rate (D_{f}) of 0.01 or less, a silica in high content of about 60 wt % or more should be added. In order to add the silica in high content having a size of nanos to micros, excellent dispersion is needed, and in order to obtain desired physical properties through excellent compatibility and reactivity with the epoxy resin by adding the silica as a filler to an epoxy composition, the silica should be surface-treated. Therefore, at the time of adding the silica in high content into the epoxy resin, a small amount of dispersion is added or the silica including a specific functional group on a surface thereof by performing the surface treatment using a wet/dry method has been mainly used.

The dielectric properties of the film generally depend on the content of the silica and the silica in high content should be added for achieving the low dielectric properties as described above; however, the addition of the silica in high content causes deterioration in film processability and mechanical physical properties. Therefore, the added content is required to be decreased by high function of the silica occupying the most portions in the composition of the film, and a novel surface treatment technology except for a surface treatment using the existing single silane coupling agent is required for preparing a high functional silica.

Meanwhile, a surface-treated inorganic filler prepared by using a silane-based coupling agent disclosed in Patent Document 1 improves close adhesion with the epoxy resin and prevents cracks of the cured product from being generated; however, has a limitation in achieving a low coefficient of thermal expansion and a low dielectric loss rate.

### PRIOR ART DOCUMENT

### Patent Document

Patent Document 1 Korean Patent Laid-Open Publication No. 2013-0037714 (WO 2012/042847)

### SUMMARY OF THE INVENTION

In the present invention, it was confirmed that an epoxy resin composition is prepared by using a surface-modified inorganic filler including an alkyl group having a low dielectric constant property and an amine group having excellent compatibility and reactivity with the epoxy resin sequentially introduced thereinto to thereby have a low degree of humidity, a low coefficient of thermal expansion, and a low dielectric loss rate, thereby completing the present invention.

The present invention has been made in an effort to provide a method for preparing a surface-modified inorganic filler by introducing the alkyl group having the low dielectric constant property and the amine group having excellent compatibility and reactivity with the epoxy resin thereinto.

In addition, the present invention has been made in an effort to provide an epoxy resin composition including the surface-modified inorganic filler.

Further, the present invention has been made in an effort to provide an insulating film manufactured using the epoxy resin composition.

According to a preferred embodiment of the present invention, there is provided a surface-modified inorganic filler including an alkyl group and an amine group sequentially introduced on a surface thereof, wherein the alkyl group and the amine group are introduced on the surface of the inorganic filler in a weight ratio between the alkyl group and the amine group of 0.5:9.5 to 4:6.

The alkyl group and the amine group introduced on the surface of the inorganic filler may have a content of 0.5 to 6 wt % based on the inorganic filler.

The alkyl group may be introduced by using a dodecyl silane coupling agent.

The amine group may be introduced by using an aminophenyl silane coupling agent.

The inorganic filler may be selected from a group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

According to another preferred embodiment of the present invention, there is provided a method for preparing a surface-modified inorganic filler, the method including: drying an inorganic filler; introducing an alkyl group on a surface of the inorganic filler by using a silane coupling agent including the alkyl group; and introducing an amine group into the inorganic filler having the alkyl group introduced thereinto by using the silane coupling agent including the amine group.

The silane coupling agent including the alkyl group may be a dodecyl silane coupling agent.

The silane coupling agent including the amine group may be an aminophenyl silane coupling agent.

The alkyl group and the amine group may be introduced on the surface of the inorganic filler in a weight ratio between the alkyl group and the amine group of 0.5:9.5 to 4:6.

The alkyl group and the amine group introduced on the surface thereof may have a content of 0.5 to 6 wt % based on the inorganic filler.

The inorganic filler may be selected from a group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

According to another preferred embodiment of the present invention, there is provided an epoxy resin composition including: the surface-modified inorganic filler as described above; an epoxy resin; and a curing agent.

The epoxy resin composition may further include a curing accelerator.

According to another preferred embodiment of the present invention, there is provided an insulating film manufactured by applying and semi-curing the epoxy resin composition as described above on a board.

A degree of humidity may be 0.2 to 0.5 wt %, and a dielectric loss rate may be 0.003 to 0.01.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

A method for preparing a surface-modified inorganic filler may include: drying an inorganic filler; introducing an alkyl group on a surface of the inorganic filler by using a silane coupling agent including the alkyl group; and introducing an amine group into the inorganic filler having the alkyl group introduced thereinto by using the silane coupling agent including the amine group. According to preferred embodiments of the present invention, after the silane coupling agent including the alkyl group having the low dielectric property is treated on the surface of the dried inorganic filler, the silane coupling agent including the amine group having excellent reactivity with the epoxy resin is additionally treated, such that the inorganic filler having an improved dispersion in the resin and largely decreased degree of humidity, coefficient of thermal expansion, and dielectric loss rate may be prepared. Hereinafter, a method for preparing the surface-modified inorganic filler for each process will be described.

First, the inorganic filler to be surface-modified is heat-dried using an oven for about 12 hours to prepare the inorganic filler having a dried surface. Here, the inorganic filler is selected from a group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate, and in particular, the silica is preferred in the preferred embodiment of the present invention; however, the inorganic filler to be surface-modified is not necessarily limited thereto within a scope for achieving the object of the present invention. Meanwhile, time required for drying the inorganic filler may be controlled depending on kinds, contents of the inorganic filler, and sizes of particles.

The dried inorganic filler is dispersed into a mixture of ethanol/distilled water and the silane coupling agent including the alkyl group is introduced thereinto. A dodecyl silane coupling agent is used in the preferred embodiment of the present invention; however, the present invention is not necessarily limited thereto, and the silane coupling agent including the alkyl group having the number of alkyl groups of 1 to 12 may be used. The silane coupling agent including the alkyl group is put thereinto, followed by stirring at a temperature of about 60 to 80° C., and is reacted with the inorganic filler for about 5 to 24 hours. In order to remove a non-reacted silane coupling agent after the surface treatment, the reactant was washed several times using ethanol, filtered, and dried under a temperature condition of 80° C., thereby finally obtaining the surface-treated inorganic filler with the dodecyl group.

Then, the inorganic filler having the alkyl group introduced thereinto is dispersed into the mixture of ethanol/distilled water, and the silane coupling agent including the amine group is introduced thereinto. An amino phenyl silane coupling agent is used in the preferred embodiment of the present invention; however, the present invention is not necessarily limited thereto. The silane coupling agent including the amine group is put thereinto, followed by stirring at a temperature of about 60 to 80° C., and is reacted with the inorganic filler for about 5 to 24 hours. In order to remove a non-reacted silane coupling agent after the surface treatment, the reactant was washed several times using ethanol, filtered, and dried under a temperature condition of 80° C., thereby finally obtaining the surface-treated inorganic filler with the alkyl group and the amine group.

At the time of surface-treating the inorganic filler using the silane coupling agent, a content in the silane coupling agent for surface-treating is defined as 0.5 to 6 wt % based on the inorganic filler, and the surface treatment is preferably performed in a content of 2 wt %. In the case in which the content of the silane coupling agent coupled on the surface of the inorganic filler is less than 0.5 wt %, the surface-modified inorganic filler has deteriorated dispersion in the epoxy resin, and in the case in which the content of the silane coupling agent coupled on the surface of the inorganic filler is more than 6 wt %, the dielectric loss rate of a resin composition is increased.

In addition, it is preferred that the alkyl group and the amine group are coupled on the surface of the inorganic filler so that a weight ratio between the alkyl group and the amine group to be introduced thereinto is 0.5:9.5 to 4:6. In the case in which the introduction ratio of the alkyl group is less than 0.5, hydrophobicity is decreased and the degree of humidity of the resin composition is increased to increase the dielectric loss rate, and in the case in which the introduction ratio of the alkyl group is more than 4, an interfacial adhesion with the epoxy resin is decreased to increase the coefficient of thermal expansion of the resin composition.

The surface-modified inorganic filler according to the preferred embodiment of the present invention as described above has a low surface tension to decrease an affinity to moisture and decrease the degree of humidity of the epoxy resin composition, thereby decreasing the dielectric loss rate of the epoxy resin composition.

The epoxy resin composition according to the preferred embodiment of the present invention includes the surface-modified inorganic filler, the epoxy resin, and a curing agent.

The epoxy resin may be at least one selected from a group consisting of a naphthalene-based epoxy resin, a bisphenol A type epoxy resin, a phenol novolac epoxy resin, a cresol novolac epoxy resin, a rubber-modified epoxy resin, and a phosphorous-based epoxy resin, but the present invention is not necessarily limited thereto.

The curing agent may be at least one selected from a group consisting of an active ester curing agent, an amino triazine novolac curing agent, an amide-based curing agent, a polyamine-based curing agent, an acid anhydride curing agent, a phenolic novolac type curing agent, a polymercaptan curing agent, and a tertiary amine curing agent, and an imidazole curing agent, but the present invention is not necessarily limited thereto.

The epoxy resin composition according to the preferred embodiment of the present invention may further include a curing accelerator for adjusting a curing time and a curing temperature. As the curing accelerator, an imidazole-based curing accelerator may be used, and at least one selected from a group consisting of 2-ethyl-methyl imidazole-4, 1-(2-cyano-ethyl)-2-alkyl imidazole, 2-phenyl imidazole, and a mixture thereof may be used, but the present invention is not limited thereto.

The epoxy resin composition according to the preferred embodiment of the present invention may be used to manufacture an insulating film or a prepreg. The insulating film may be manufactured by coating and curing the insulating resin composition according to the preferred embodiment of the present invention on a predetermined substrate such as polyethyleneterephthalate (PET). The manufactured insulating film may be variously utilized, and in general, may be used in order to form a build-up insulating layer of a multilayered printed circuit board. That is, the insulating films are multilayered on the substrate having a predetermined wiring pattern formed therein, and laminated on the board by vacuum. Meanwhile, the prepreg is manufactured by preparing the insulating resin composition according to the preferred embodiment of the present invention to be a varnish, impregnating a glass fabric, or the like, into the varnish, and performing a drying process. The manufactured prepreg as described above includes the glass fiber therein to have excellent thermal stability and mechanical stability; however, it is difficult to be used in other layers rather than a core layer of the multilayered printed circuit board due to weight and volume occupied by the glass fiber.

Meanwhile, the insulating film or the prepreg manufactured using the insulating resin composition according to the preferred embodiment of the present invention may be used to manufacture a printed circuit board. That is, the printed circuit board may be manufactured by multilayering and pressing the insulating film or the prepreg on the board having the predetermined circuit pattern formed therein. The insulating film or the prepreg as described above may serve as an insulating layer of the printed circuit board.

The insulating film manufactured using the epoxy resin composition including the surface-modified inorganic filler according to the preferred embodiment of the present invention may have a low degree of humidity of 0.2 to 0.5 wt %, and the thus-obtained low dielectric loss rate of 0.003 to 0.01.

Hereinafter, the present invention will be described in more detail with reference to the following examples and comparative examples; but is not limited thereto.

### Comparative Example 1

A silica used in the present invention was dried at 100° C. for about 12 hours before using it for an experiment. (3-glycidoxypropyl)methyldiethoxysilane (GPTMS) was used for introduction of an epoxide group. The silica was dispersed into a mixture of ethanol/distilled water and GPTMS was added thereto, followed by stirring at a temperature of about 60 to 80° C., and reacted for about 5 to 24 hours. In order to remove a non-reacted silane coupling agent after the surface treatment, the reactant was washed with ethanol several times, filtered, and dried under a temperature condition of 80° C., thereby finally obtaining a surface-treated silica (GPTMS-SiO₂) with the epoxide group.

Then, the surface-treated silica was prepared as a slurry by using a methyl ethyl ketone (MEK) solution, the prepared slurry was added to an epoxy resin and mixed with stirring, and amino triazine novolac as a curing agent and an active ester were used to prepare a polymer complex sample. At the time of preparing the epoxy composition, the content of the silica was fixed as 75 wt %.

### Comparative Example 2

A silica used in the present invention was dried at 100° C. for about 12 hours before using it for an experiment. A dodecyl silane coupling agent was used for introduction of an alkyl group. The silica was dispersed into a mixture of ethanol/distilled water and the dodecyl silane coupling agent was added thereto, followed by stirring at a temperature of about 60 to 80° C., and reacted for about 5 to 24 hours. In order to remove a non-reacted silane coupling agent after the surface treatment, the reactant was washed with ethanol several times, filtered, and dried under a temperature condition of 80° C., thereby finally obtaining a surface-treated silica (C—SiO₂) with the dodecyl group.

Then, the surface-treated silica was prepared as a slurry by using a methyl ethyl ketone (MEK) solution, the prepared slurry was added to an epoxy resin and mixed with stirring, and amino triazine novolac as a curing agent and an active ester were used to prepare a polymer complex sample. At the time of preparing the epoxy composition, the content of the silica was fixed as 75 wt %.

### Comparative Example 3

A silica used in the present invention was dried at 100° C. for about 12 hours before using it for an experiment. An aminophenyl silane coupling agent (APS) was used for introduction of an amine group. The silica was dispersed into a mixture of ethanol/distilled water and the dodecyl silane coupling agent was added thereto, followed by stirring at a temperature of about 60 to 80° C., and reacted for about 5 to 24 hours. In order to remove a non-reacted silane coupling agent after the surface treatment, the reactant was washed with ethanol several times, filtered, and dried under a temperature condition of 80° C., thereby finally obtaining a surface-treated silica (APS—SiO₂) with the amine group.

Then, the surface-treated silica was prepared as a slurry by using a methyl ethyl ketone (MEK) solution, the prepared slurry was added to an epoxy resin and mixed with stirring, and amino triazine novolac as a curing agent and an active ester were used to prepare a polymer complex sample. At the time of preparing the epoxy composition, the content of the silica was fixed as 75 wt %.

### Example 1

A silica used in the present invention was dried at 100° C. for about 12 hours before using it for an experiment. A dodecyl silane coupling agent and an aminophenyl silane coupling agent (APS) were used for introduction of an alkyl group and an amine group. The silica was dispersed into a mixture of ethanol/distilled water and the dodecyl silane coupling agent was added thereto, followed by stirring at a temperature of about 60 to 80° C., and reacted for about 5 to 24 hours. In order to remove a non-reacted silane coupling agent after the surface treatment, the reactant was washed with ethanol several times, filtered, and dried under a temperature condition of 80° C., thereby finally obtaining a surface-treated silica (C—SiO₂) with the dodecyl group. For a second surface treatment, the dodecyl surface-treated silica was dispersed into a mixture of ethanol/distilled water and the aminophenyl silane coupling agent was added thereto, followed by stirring at a temperature of about 60 to 80° C., and reacted for about 5 to 24 hours. In order to remove a non-reacted silane coupling agent after the surface treatment, the reactant was washed with ethanol several times, filtered, and dried under a temperature condition of 80° C., thereby finally obtaining a surface-treated silica (C/APS—SiO₂) with the dodecyl group and the amine group. At the time of performing the surface treatment of the silica, a content in the silane coupling agent is defined as 0.5 to 6 wt % based on the silica, and the surface treatment is preferably performed in a content of 2 wt %.

The surface-treated silica having a ratio between the dodecyl group and the amine group of 0.5:9.5 was prepared as a slurry by using a methyl ethyl ketone (MEK) solution, the prepared slurry was added to an epoxy resin and mixed with stirring, and amino triazine novolac as a curing agent was used to prepare a polymer complex sample. At the time of preparing the epoxy composition, the content of the silica was fixed as 75 wt %.

### Example 2

A surface treatment method of a silica according to Example 2 is the same as that of Example 1, except that the ratio between the dodecyl group and the amine group is 1:9.

The surface-treated silica was prepared as a slurry by using a methyl ethyl ketone (MEK) solution, the prepared slurry was added to an epoxy resin and mixed with stirring, and amino triazine novolac as a curing agent was used to prepare a polymer complex sample. At the time of preparing the epoxy composition, the content of the silica was fixed as 75 wt %.

### Example 3

A surface treatment method of a silica according to Example 3 is the same as that of Example 1, except that the ratio between the dodecyl group and the amine group is 2:8.

The surface-treated silica was prepared as a slurry by using a methyl ethyl ketone (MEK) solution, the prepared slurry was added to an epoxy resin and mixed with stirring, and amino triazine novolac as a curing agent was used to prepare a polymer complex sample. At the time of preparing the epoxy composition, the content of the silica was fixed as 75 wt %.

### Example 4

A surface treatment method of a silica according to Example 4 is the same as that of Example 1, except that the ratio between the dodecyl group and the amine group is 3:7.

The surface-treated silica was prepared as a slurry by using a methyl ethyl ketone (MEK) solution, the prepared slurry was added to an epoxy resin and mixed with stirring, and amino triazine novolac as a curing agent was used to prepare a polymer complex sample. At the time of preparing the epoxy composition, the content of the silica was fixed as 75 wt %.

### Example 5

A surface treatment method of a silica according to Example 5 is the same as that of Example 1, except that the ratio between the dodecyl group and the amine group is 4:6.

The surface-treated silica was prepared as a slurry by using a methyl ethyl ketone (MEK) solution, the prepared slurry was added to an epoxy resin and mixed with stirring, and amino triazine novolac as a curing agent was used to prepare a polymer complex sample. At the time of preparing the epoxy composition, the content of the silica was fixed as 75 wt %.

After the resin compositions prepared by Comparative Examples and Examples above were applied and semi-cured on a board to manufacture an insulating film and processed so as to have a predetermined standard, the degree of humidity, a coefficient of thermal expansion, and a dielectric constant were measured.

TABLE 1

| | Coefficient of Thermal | Dielectric | Degree of Humidity |
|---|---|---|---|
| | Expansion (ppm) | Loss Rate | (%) |
| Comparative | 17.6 | 0.0070 | 0.36 |
| Example 1 | | | |
| Comparative | 15.2 | 0.0052 | 0.27 |
| Example 2 | | | |
| Comparative | 13.0 | 0.0062 | 0.33 |
| Example 3 | | | |
| Example 1 | 13.0 | 0.0062 | 0.33 |
| Example 2 | 13.3 | 0.0060 | 0.30 |
| Example 3 | 13.5 | 0.0057 | 0.29 |
| Example 4 | 14.2 | 0.0055 | 0.28 |
| Example 5 | 14.6 | 0.0055 | 0.28 |

It may be appreciated from Table 1 above that the insulating films manufactured using the silica treated with the single silane coupling agent according to Comparative Examples 1 to 3 had relatively high coefficient of thermal expansion and relatively high dielectric loss rate as compared to the insulating films manufactured according to Examples. However, it may be appreciated that in Examples 1 to 5, the alkyl group and the amine group were sequentially introduced into the silica, such that a low coefficient of thermal expansion and a low dielectric loss rate were achieved.

With the method for preparing the surface-modified inorganic filler according to the preferred embodiments of the present invention, an affinity to the moisture of the inorganic filler may be decreased to decrease the degree of humidity affecting the dielectric loss rate of the epoxy resin composition.

In addition, with the epoxy resin composition prepared by using the surface-modified inorganic filler according to the preferred embodiment of the present invention, the mechanical physical properties of the composition may not be deteriorated due to excellent dispersion of the inorganic filler and the decreased coefficient of thermal expansion may be provided due to excellent interfacial adhesion.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A surface-modified inorganic filler comprising an alkyl group and an amine group sequentially introduced on a surface thereof,
wherein the alkyl group and the amine group are introduced on the surface of the inorganic filler in a weight ratio between the alkyl group and the amine group of 0.5:9.5 to 4:6.

2. The surface-modified inorganic filler as set forth in claim 1, wherein the alkyl group and the amine group introduced on the surface thereof have a content of 0.5 to 6 wt % based on the inorganic filler.

3. The surface-modified inorganic filler as set forth in claim 1, wherein the alkyl group is introduced by using a dodecyl silane coupling agent.

4. The surface-modified inorganic filler as set forth in claim 1, wherein the amine group is introduced by using an aminophenyl silane coupling agent.

5. The surface-modified inorganic filler as set forth in claim 1, wherein it is selected from a group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

6. A method for preparing a surface-modified inorganic filler, the method comprising:
drying an inorganic filler;
introducing an alkyl group on a surface of the inorganic filler by using a silane coupling agent including the alkyl group; and
introducing an amine group into the inorganic filler having the alkyl group introduced thereinto by using the silane coupling agent including the amine group.

7. The method as set forth in claim 6, wherein the silane coupling agent including the alkyl group is a dodecyl silane coupling agent.

8. The method as set forth in claim 6, wherein the silane coupling agent including the amine to group is an aminophenyl silane coupling agent.

9. The method as set forth in claim 6, wherein the alkyl group and the amine group are introduced on the surface of the inorganic filler in a weight ratio between the alkyl group and the amine group of 0.5:9.5 to 4:6.

10. The method as set forth in claim 6, wherein the alkyl group and the amine group introduced on the surface thereof have a content of 0.5 to 6 wt % based on the inorganic filler.

11. The method as set forth in claim 6, wherein the inorganic filler is selected from a group consisting of silica, alumina, barium sulfate, talc, clay, mica powder, aluminum hydroxide, magnesium hydroxide, calcium carbonate, magnesium carbonate, magnesium oxide, boron nitride, aluminum borate, barium titanate, calcium titanate, magnesium titanate, bismuth titanate, titanium oxide, barium zirconate, and calcium zirconate.

12. An epoxy resin composition comprising:
the surface-modified inorganic filler as set forth in claim 1;
an epoxy resin; and
a curing agent.

13. The epoxy resin composition as set forth in claim 12, further comprising a curing accelerator.

14. An insulating film manufactured by applying and semi-curing the epoxy resin composition as set forth in claim 12 on a board.

15. The insulating film as set forth in claim 14, wherein a degree of humidity is 0.2 to 0.5 wt %, and a dielectric loss rate is 0.003 to 0.01.
